(19) United States
(12) Patent Application Publication
(10) Pub. No.: US 2016/0223809 A1
(43) Pub. Date: Aug. 4, 2016

(54) CORRECTION OF LASER DIODE BAR ERROR

(71) Applicant: Nissim Pilossof, Burnaby (CA)

(72) Inventor: Nissim Pilossof, Burnaby (CA)

(21) Appl. No.: 14/612,332

(22) Filed: Feb. 3, 2015

(51) Int. Cl. G02B 26/08; H01S 5/00

(52) U.S. Cl. CPC G02B 26/0833; H01S 5/0071

(57) ABSTRACT

A method for dynamic correction of cross-array errors in an optical systems incorporating laser diode bar (100) including emitting laser beams from a plurality of emitters (101, 102) on the laser diode bar; analyzing the beams produced from each of the plurality of emitters; measuring a deviation of each emitter relative to a straight line (201); transferring the deviation for each of the emitters relative to the straight line to a controller (810); and driving a plurality of actuators connected to micro-mirrors to correct for the deviation from the straight line of each of the emitters.

### FIELD OF THE INVENTION

The present invention relates to methods and apparatus for correcting of cross-array error of plurality of laser bar emission to emit in aligned straight line.

### BACKGROUND OF THE INVENTION

Laser diode bars consists of individual emitters arranged in a line. The manufacturing process of the bars leads to emitters not being aligned in a straight line. This intrinsic property of the bars is referred to as “cross-array errors” or “bar smile.” Typical bar smile 12 is illustrated in FIG. 1. Typical bar smile can vary from sub-micron to several microns values. The net result of the bar smile is that it decreases the laser brightness in the fast-axis direction, which otherwise is only diffraction limited. The reason for this is that the smile prevents the fast axis collimator (FAC) to be positioned correctly for each emitter in the array. Usually the bar smile is defined as peak-to-valley (P-V) position variation in cross-array direction of the individual array members (emitters) from a straight line obtained by linear least squares fitting of their geometrical positions.

One of the properties of the laser bar smile is that it generally depends in the laser current. Typical example is shown on FIG. 2 illustrating measurement results of individual emitters' positions deviation from a straight line at four different currents 20 A, 35 A, 50 A, and 65 A. As shown in this particular example, the bar smile (P-V position variation) can be as low as 0.91 μm at 20 A and as high as 1.2 g. at 50 A laser current. It is important to notice that as though in most cases the lower smile corresponds to lower currents there are cases, as the illustrated on FIG. 2, in which the dependence is not monotonic and lower currents can have higher smile value.

The smile effect is illustrated on FIG. 3. Emitters 100 are positioned in the plane constituted by planes 201 but are not arranged in a straight line. After passing through the FAC 301, which vertex 303 lies in the main optical plane 202, only beams originating from emitters 102 that are positioned in the main optical plane 203 will propagate parallel to this plane. In the focal plane 202 of the FAC all beams will form spots arranged in a straight line. In any subsequent plane 203 downstream though, the spots produced by beams originating from emitters 101 that are not positioned in the main optical plane will be deviated. The further the beams propagate downstream, the bigger this deviation from a straight line will be as illustrated by the broken lines 204.

Consider a typical application of an optical system imaging the emitters' fast-axis onto a target with magnification for example ×20 and overlapping their slow-axes. If the focal length of the FAC is 1 mm, which is a typical value, a smile of 2 microns will lead to a beam with divergence increased only by about 1 mRad (depending on the particular cross-array distribution of the emitters), but a spot with spatial distribution very different to the one compared to the case of zero smile. For a parabolic shaped smile of P−V=2 μm these spatial and angular distributions are illustrated on FIGS. 4a and 4b respectively. For comparison the same figures present the spot characteristics of the same optical system incorporating a laser bar with zero smile.

Prior art shown in U.S. Pat. No. 5,854,651 uses one-time adjustable mirrors or parallel plane plates to correct the beams propagation directions. U.S. Pat. No. 5,861,992 uses individual FAC associated to each emitter and displaced in fast-axis direction to compensate for the corresponding emitter displacement. Another smile correction approach using phaseplates with continuously-varying wedge surfaces correcting the pointing of each emitter after the FAC has been collimated is illustrated in an industrial product reported in an article by Roy McBride, Natalia Trela, Jozef J. Wendland, Howard J. Baker, Proc. SPIE 8039, Laser Technology for Defense and Security VII, 80390F, 2011 and shown at: http://www.powerphotonic.com/wpcontent/uploads/2014/01/Smile-Corrector-Data-Sheet.pdf, which presents methods to correct smile of single laser bar at a single particular current.

### SUMMARY OF THE INVENTION

Briefly, according to one aspect of the present invention a method for dynamic correction of cross-array errors in an optical systems incorporating laser diode bar including emitting laser beams from a plurality of emitters on the laser diode bar; analyzing the beams produced from each of the plurality of emitters; measuring a deviation of each emitter relative to a straight line; transferring the deviation for each of the emitters relative to the straight line to a controller; and driving a plurality of actuators connected to micro-mirrors to correct for the deviation from the straight line of each of the emitters.

These and other objects, features, and advantages of the present invention will become apparent to those skilled in the art upon a reading of the following detailed description when taken in conjunction with the drawings wherein there is shown and described an illustrative embodiment of the invention.

### BRIEF DESCRIPTION OF THE DRAWINGS

FIG. 1 represents an image of a typical bar smile (prior art);

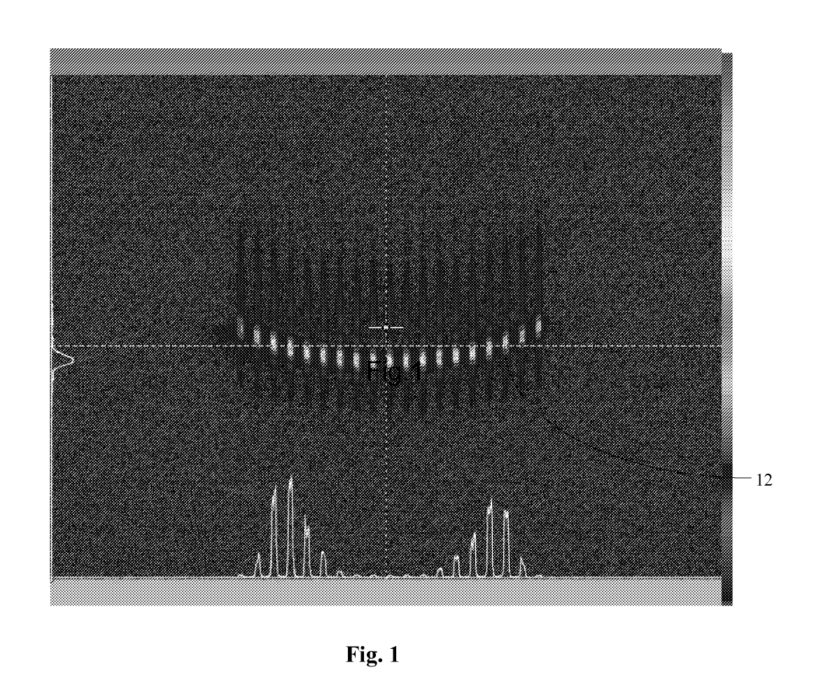

FIG. 2 shows a diagram of fast axis deviation of plurality of emitters operated at different currents;

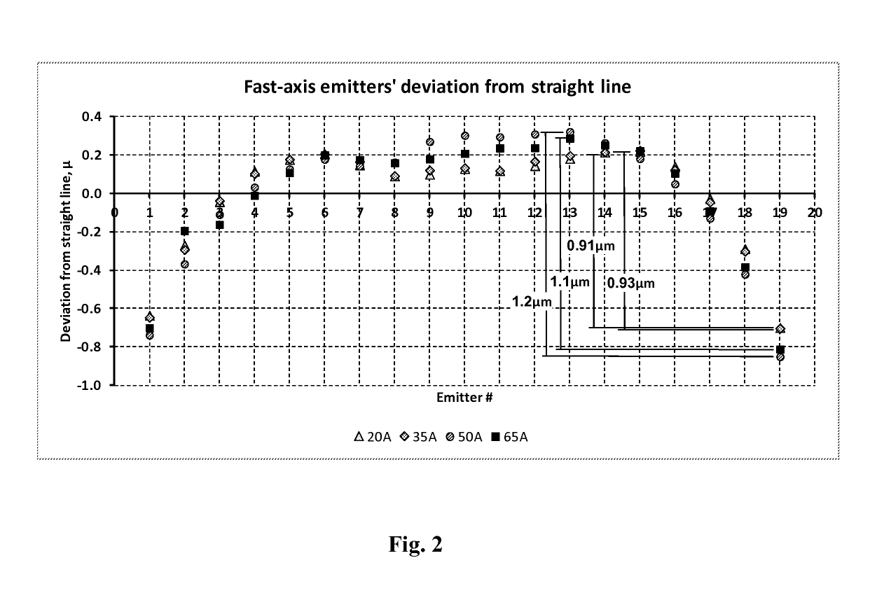

FIG. 3 shows a smile bar effect generated by an arrangement of plurality of emitters and fast axis collimator;

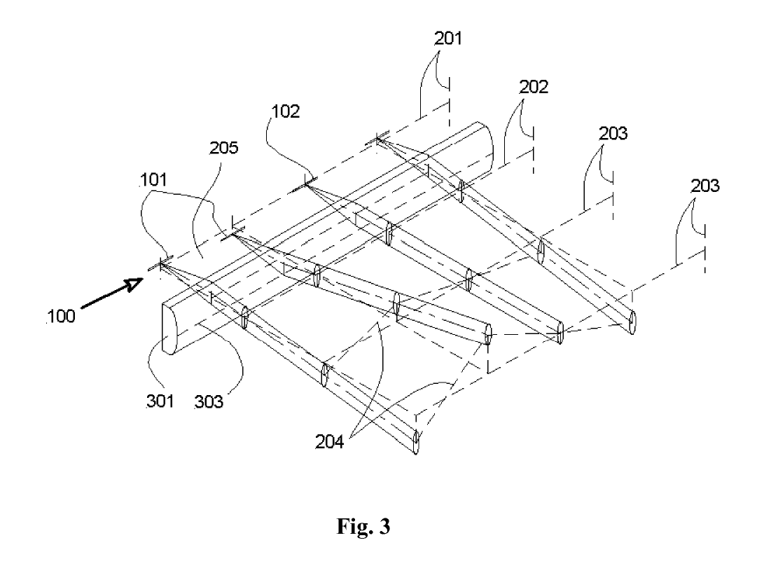

FIGS. 4a and 4b show a spot with spatial and angular distributions generated by smile of two microns;

FIG. 5a shows an apparatus arrangement applying a dynamic correction of cross-array errors of laser diode bars with a mirror for each emitter;

FIG. 5b shows an apparatus arrangement applying a dynamic correction of cross-array errors of laser diode bars with a mirror common to two emitters;

FIGS. 6a and 6b show results from angle correction of the system from diagrams shown in FIGS. 4a and 4b to corrected results in diagrams illustrated by FIGS. 6a and 6b; and

FIG. 7 shows a closed loop system for dynamic correction of the array cross-errors using beam analyzing and angle correction.

### DETAILED DESCRIPTION OF THE INVENTION

In the following detailed description, numerous specific details are set forth in order to provide a thorough understanding of the disclosure. However, it will be understood by those skilled in the art that the teachings of the present disclosure may be practiced without these specific details. In other instances, well-known methods, procedures, components and circuits have not been described in detail so as not to obscure the teachings of the present disclosure.

While the present invention is described in connection with one of the embodiments, it will be understood that it is not intended to limit the invention to this embodiment. On the contrary, it is intended to cover alternatives, modifications, and equivalents as covered by the appended claims. The object of this invention is to provide a method for dynamic correction of cross-array errors (bar smile) of laser diode bars including current dependent cross-array errors.

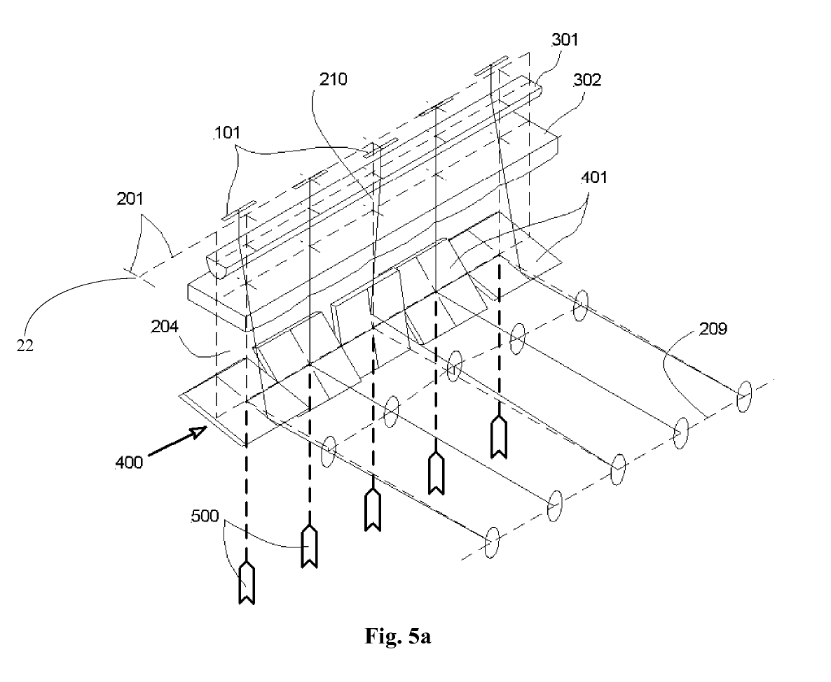

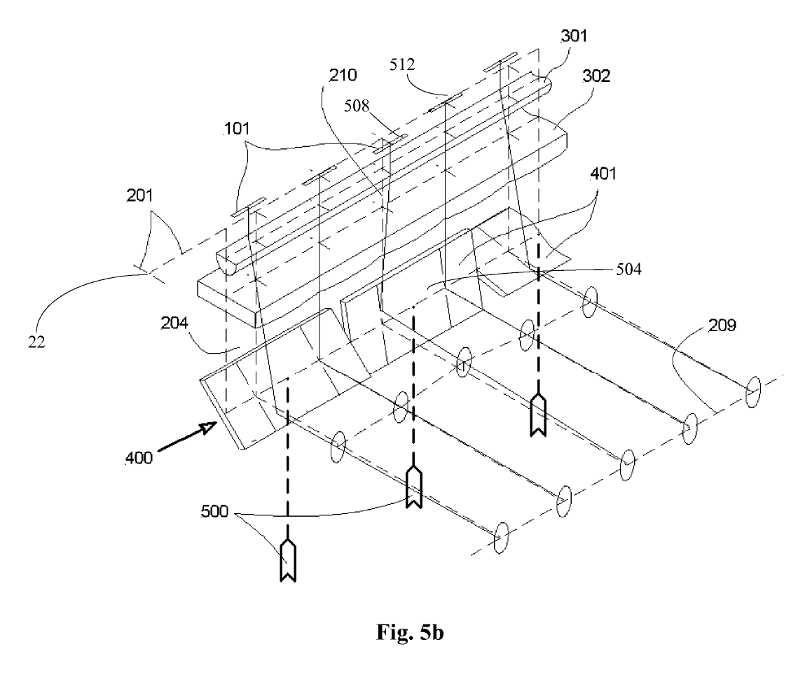

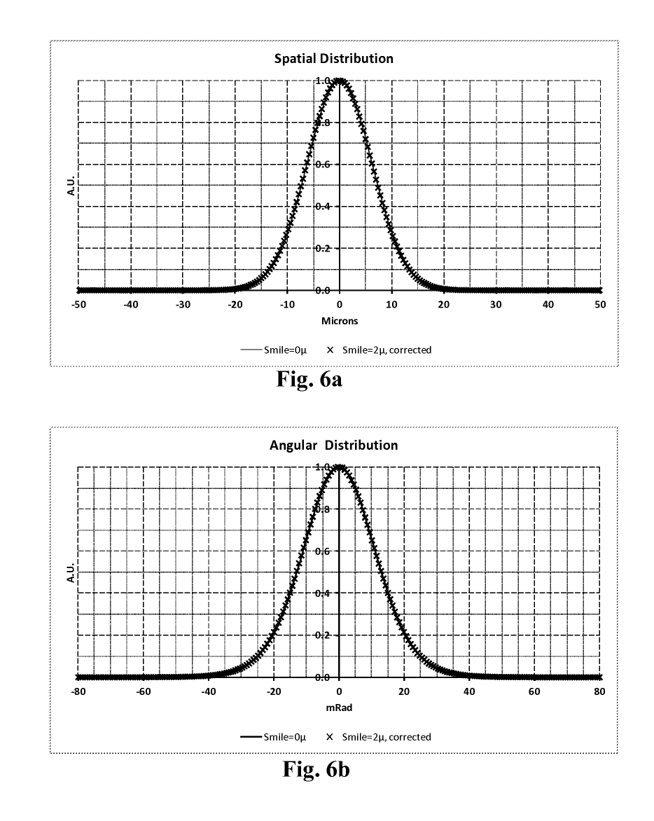

FIGS. 5a, 5b, and 6 illustrate the invention. The laser bar emitters 101 are positioned in the plane 201 and deviate from a straight line 22. The beams emanating from the emitters 101 are being collimated by the FAC 301 and the slow axis collimator (SAC) 302. Due to the cross-array positioning errors after the FAC the beams from the individual emitters do not propagate parallel to the main optical plane 204, but at different angles depending on the cross-array positioning error of each emitter. The correcting element is an array of micro-mirrors 400 with each micro-mirror 401 dedicated to a single emitter from emitters 101 as shown in FIG. 5a. Each micro-mirror 401 is dedicated to a single emitter 101 by selectively choosing the angle of this mirror relative to the optical axis 210. The beams from all emitters can be made to propagate parallel or to intersect any chosen line 209 downstream the optical system, as illustrated.

FIG. 5b shows that micro-mirror 504 of the micro-mirrors array 400 is dedicated to a group of neighboring emitters such as 508 and 512, the correction applied will be the averaged for this group of emitters. The angle of the array members is set by means of actuators 500. The actuators can be of electrostatic, magnetic, or any other type used in micromechanical technology.

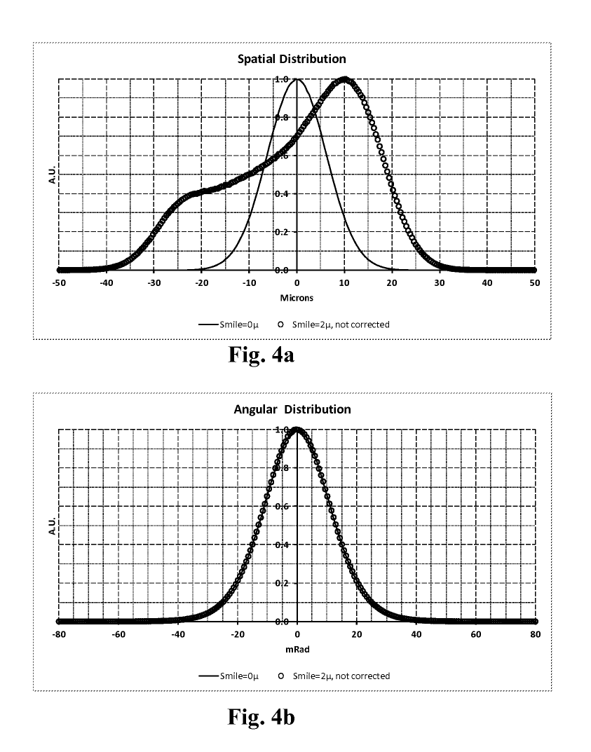

The result of such angle correction of the system from FIGS. 4a and 4b is illustrated on FIGS. 6a and 6b. Array 400 can be successfully replaced by an adaptive mirror, undisrupted reflecting surface locally deformed to provide for different angles of reflection. In less demanding applications, where some residual error can be permitted, one correcting mirror can serve two of more members of the laser array as illustrated on FIG. 5b.

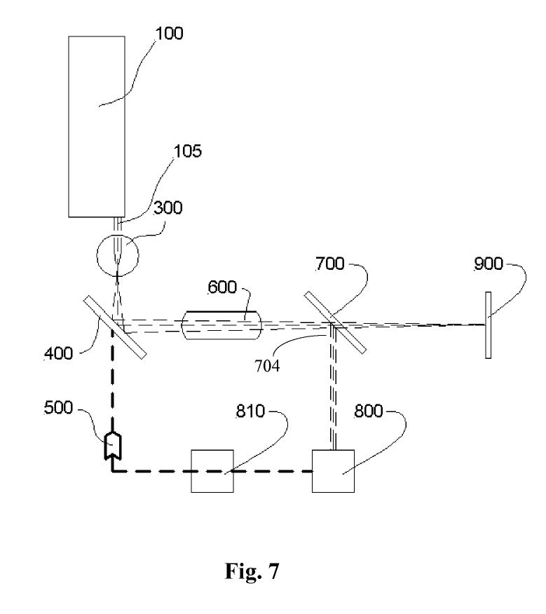

To take full advantage of the proposed dynamic correction of the array cross-errors, a closed-loop beam analyzing and angle correction is preferable. An exemplary system is illustrated on FIG. 7. The beams 105 emitted from the individual emitters of the laser diode bar 100 are collimated by the FAC and SAC, depicted for simplicity as a single entity 300, and reflected by the individual members of the array 400. After being shaped, partially or finally by any optical elements 600 in the system, a small amount, in terms of energy, of the beam 704 is being sampled by a beam sampler 700 and deviated to a beam analyzer 800. The beam analyzer is designed to sense spatial and/or angular position of the beams. The beam analyzer can be based on a multi-pixel light sensor like charge-coupled device (CCD) or complementary metal-oxide-semiconductor (CMOS) or any means suitable for the purpose. Alternatively single-pixel position sensitive detectors known as PSD can be used. These same devices, single or multi pixel, when positioned in the focal plane of simple lens added in front of them, will become beam angle sensors.

The results from the beam analyzing are being transferred to a controller 810 which drives the actuators 500 setting angles of the individual members of the array 400 in a manner to provide parallel propagation of the beams or their intersection on a single line (illustrated) on the target 900, depending on the application.

The invention has been described in detail with particular reference to certain preferred embodiments thereof, but it will be understood that variations and modifications can be effected within the scope of the invention.

### PARTS LIST

12 bar smile
22 straight line
100 emitter bar (laser diode bar)
101 emitters
102 emitters
105 beams
201 plane
202 plane
203 plane
204 deviation from focal plane
209 line downstream the optical system
210 optical axis
300 FAC and SAC
301 fast axis collimator (FAC)
302 slow axis collimator (SAC)
303 fast axis collimator vertex
400 array of micro-mirrors
401 micro-mirror
500 actuators for each micro-mirrors
504 micro mirror that handle more than one emitter
508 first emitter that emits towards micro-mirror 504
512 second emitter that emits towards micro-mirror 504
600 optical element
700 beam sampler
704 deviated beam energy
800 beam analyzer
810 controller
900 imaging target

1. A method for dynamic correction of cross-array errors in an optical systems incorporating laser diode bar comprising:
emitting laser beams from a plurality of emitters on the laser diode bar;
analyzing the beams produced from each of the plurality of emitters;
measuring a deviation of each emitter relative to a straight line;
transferring the deviation for each of the emitters relative to the straight line to a controller; and
driving a plurality of actuators connected to micro-mirrors to correct for the deviation from the straight line of each of the emitters.

2. The method according to claim 1 wherein the beams are analyzed by a multi-pixel light sensor device.

3. The method according to claim 1 wherein each of the micro-mirrors is adapted to correct for the deviation of a single emitter.

4. A method for dynamic correction of cross-array errors in an optical systems incorporating a laser diode bar comprising:
emitting laser beams from a plurality of emitters on the laser bar;
analyzing beams produced from each of the plurality of emitters;
measuring a deviation of groups of emitters relative to a straight line;
transferring the deviation for each of the groups of emitters relative to the straight line to a controller; and
driving a plurality of micro-mirrors actuators to correct for the deviation from the straight line of each of the groups of emitters.

5. The method according to claim 4 wherein correction of the deviation the micro-mirror actuators is applied to the groups of emitters by averaging deviation produced by each group of emitters.

6. The method according to claim 4 wherein the beams are analyzed by a multi pixel light sensor device.

7. The method according to claim 4 wherein the beams are analyzed by a single pixel light sensor device.

8. The method according to claim 4 wherein a small amount of energy is sampled by a beam sampler and deviated to the beam analyzer wherein the beam analyzer is designed to sense spatial position or angular position or both spatial and angular positions of the beams.

9. A system for dynamic correction of cross-array errors in an optical systems incorporating laser diode bar comprising:
laser beams emit from a plurality of emitters positioned on the laser bar;
the beams produced from each of the plurality of emitters are analyzed;
a deviation of each emitter relative to a straight line is measured;
the deviation for each of the emitters relative to the straight line is transferred to a controller; and
a plurality of actuators connected to micro-mirrors is driven to correct for the deviation from the straight line of each of the emitters.
